(19) United States
(12) Patent Application Publication
(10) Pub. No.: US 2025/0234490 A1
(43) Pub. Date: Jul. 17, 2025

(54) HEAT DISSIPATION ASSEMBLY, AND CIRCUIT SYSTEM

(71) Applicant: Delta Electronics, Inc., Taoyuan City (TW)

(72) Inventors: Chia-Wei HSU, Taoyuan City (TW); Yen-Kun LIOU, Taoyuan City (TW); Hui-Lun CHIN, Taoyuan City (TW); Yi-Fan LIN, Taoyuan City (TW); Chih-Wei CHAN, Taoyuan City (TW)

(21) Appl. No.: 18/670,424

(22) Filed: May 21, 2024

(30) Foreign Application Priority Data
Jan. 12, 2024 (CN) 202420081812.2

(51) Int. Cl. H05K 7/20

(52) U.S. Cl. CPC H05K 7/20336; H05K 7/2039

(57) ABSTRACT

A heat dissipation assembly is provided. The heat dissipation assembly includes a heat source, an upper cover, and a heat dissipation device. The upper cover includes a first upper cover surface and a second upper cover surface. The first upper cover surface receives the thermal energy from the heat source. The heat dissipation device is located under the upper cover and adjacent to the second upper cover surface to cool the second upper cover surface. The upper cover is a thermoelectric generator chip.

### CROSS REFERENCE TO RELATED APPLICATIONS

This application claims priority of China Utility Model application No. 202420081812.2, filed on Jan. 12, 2024, the entirety of which is incorporated by reference herein.

### BACKGROUND OF THE INVENTION

### Field of the Invention

The invention relates to a heat dissipation assembly and a circuit system, and in particular it relates to a heat dissipation assembly and a circuit system that may recover heat.

### Description of the Related Art

As the performance of central processing units (CPUs) and graphics processing units (GPUs) continues to improve, there has been a concomitant increase in energy consumption. The waste heat generated by central processing units and graphics processing units also continues to increase, making it more difficult to dissipate heat. After a long period, the accumulation of this wasted energy is quite huge.

Therefore, there is a need for a heat dissipation assembly and circuit system that can effectively dissipate heat and achieve heat recovery.

### BRIEF SUMMARY OF THE INVENTION

An embodiment of the present invention provides a heat dissipation assembly, including a heat source, an upper cover, and a heat dissipation device. The upper cover includes a first upper cover surface and a second upper cover surface. The first upper cover surface receives the thermal energy from the heat source. The heat dissipation device is located under the upper cover and adjacent to the second upper cover surface to cool the second upper cover surface. The upper cover is a thermoelectric generator chip

In some embodiments, the heat source is in direct contact with the first upper cover surface. In some embodiments, a temperature of the first upper cover surface is higher than a temperature of the second upper cover surface. In some embodiments, the heat dissipation assembly further includes a lower cover located under the heat dissipation device. The lower cover includes a first lower cover surface and a second lower cover surface. The first lower cover surface receives the thermal energy from the heat source. The second lower cover surface is adjacent to the heat dissipation device. A temperature of the first lower cover surface is higher than a temperature of the second lower cover surface. In some embodiments, the heat dissipation assembly further includes a heat pipe. The heat pipe is in contact with the heat source to conduct the thermal energy from the heat source away from the heat source. In some embodiments, the heat pipe is in contact with the first upper cover surface to conduct the thermal energy from the heat source to the first upper cover surface. In some embodiments, the heat dissipation assembly further includes a fin disposed adjacent to the upper cover. The heat pipe is in contact with the fin to conduct the thermal energy from the heat source to the fin. In some embodiments, the heat pipe is in contact with the first upper cover surface and the fin, so as to conduct the thermal energy from the heat source to the first upper cover surface and the fin.

An embodiment of the present invention provides a heat dissipation assembly, including a heat source, a lower cover, and a heat dissipation device. The lower cover includes a first lower cover surface, and a second lower cover surface. The first lower cover surface receives the thermal energy from the heat source. The heat dissipation device is located above the lower cover and adjacent to the second lower cover surface to cool the second lower cover surface. The lower cover is a thermoelectric generator chip.

In some embodiments, the heat source is in direct contact with the first lower cover surface. In some embodiments, a temperature of the first lower cover surface is higher than a temperature of the second lower cover surface. In some embodiments, the heat dissipation assembly further includes an upper cover located above the heat dissipation device. The upper cover includes a first upper cover surface, and a second upper cover surface. The first upper cover surface receives the thermal energy from the heat source. The second upper cover surface is adjacent to the heat dissipation device. A temperature of the first upper cover surface is higher than a temperature of the second upper cover surface. In some embodiments, the heat dissipation assembly further includes a heat pipe. The heat pipe is in contact with the heat source to conduct the thermal energy from the heat source away from the heat source. In some embodiments, the heat pipe is in contact with the first lower cover surface to conduct the thermal energy from the heat source to the first lower cover surface. In some embodiments, the heat dissipation assembly further includes a fin disposed adjacent to the lower cover. The heat pipe is in contact with the fin to conduct the thermal energy from the heat source to the fin. In some embodiments, the heat pipe is in contact with the first lower cover surface and the fin, so as to conduct the thermal energy from the heat source to the first lower cover surface and the fin.

An embodiment of the present invention provides a circuit system, including the heat dissipation assembly, a boost circuit, and an electronic element. The heat dissipation assembly generates a voltage. The boost circuit adjusts the voltage from the heat dissipation assembly. The electronic element receives the voltage adjusted by the boost circuit.

In some embodiments, the electronic element is one or more of a rechargeable battery, a capacitor, a keyboard light, a memory access, and a heat dissipation device power. In some embodiments, the circuit system, further includes an auxiliary power supply, and a control circuit. The auxiliary power supply generates a second voltage. When the voltage generated by the heat dissipation assembly is insufficient to drive the electronic element, the control circuit provides the second voltage generated by the auxiliary power supply to the electronic element. In some embodiments, when the voltage generated by the heat dissipation assembly is sufficient to drive the electronic element, the control circuit provides the voltage generated by the heat dissipation assembly to the electronic element.

### BRIEF DESCRIPTION OF THE DRAWINGS

The present invention may be more fully understood by reading the subsequent detailed description and examples with references made to the accompanying drawings, wherein:

FIG. 1 is a schematic view of a heat dissipation assembly according to some embodiments of the present disclosure.

FIG. 2 is a schematic view of a heat dissipation assembly according to some embodiments of the present disclosure.

FIG. 3 is a schematic view of a heat dissipation assembly according to some embodiments of the present disclosure.

FIG. 4 is a schematic view of a heat dissipation assembly according to some embodiments of the present disclosure.

FIG. 5 is a schematic view of a circuit system according to some embodiments of the present disclosure.

### DETAILED DESCRIPTION OF THE INVENTION

The present disclosure may be more clearly understood by referring to the following description and the appended drawings. It should be noted that, for the sake of the simplicity of the drawings and comprehensibility for readers, only a portion of the light-emitting unit is illustrated in multiple figures in the present disclosure, and the specific components in the figures are not drawn to scale. In addition, the number and size of each component in the drawings merely serve as an example, and are not intended to limit the scope of the present disclosure. Furthermore, similar and/or corresponding numerals may be used in different embodiments for describing some embodiments simply and clearly, but they do not represent any relationship between different embodiments and/or structures discussed below.

Certain terms may be used throughout the present disclosure and the appended claims to refer to particular elements. Those skilled in the art will understand that electronic device manufacturers may refer to the same components by different names. The present specification is not intended to distinguish between components that have the same function but different names. In the following specification and claims, the words “including”, “comprising”, “having” and the like are open-ended words, so they should be interpreted as meaning “including but not limited to . . . ” Therefore, when the terms “including”, “comprising”, and/or “having” are used in the description of the disclosure, the presence of corresponding features, regions, steps, operations and/or components is specified without excluding the presence of one or more other features, regions, steps, operations and/or components.

In addition, in this specification, relative expressions may be used. For example, “lower”, “bottom”, “higher” or “top” are used to describe the position of one element relative to another. It should be noted that if a device is flipped upside down, an element that is “lower” will become an element that is “higher”.

When a corresponding component (i.e. a film layer or region) is referred to as “on another component”, it may be directly on another component, or there may be other components in between. On the other hand, when a component is referred “directly on another component”, there is no component between the former two. In addition, when a component is referred “on another component”, the two components have an up-down relationship in the top view, and this component can be above or below the other component, and this up-down relationship depends on the orientation of the device.

The terms “about,”, “essentially,” or “substantially” are generally interpreted as within 20% of a given value or range, or as interpreted as within 10%, 5%, 3%, 2%, 1%, or 0.5% of a given value or range.

In the present application, when mentioning that the A element overlaps the B element, it means to include at least partial overlap.

It should be understood that, although the terms “first”, “second” etc. may be used herein to describe various elements, layers and/or portions, and these elements, layers, and/or portions should not be limited by these terms. These terms are only used to distinguish one element, layer, or portion. Thus, a first element, layer or portion discussed below could be termed a second element, layer or portion without departing from the teachings of some embodiments of the present disclosure. In addition, for the sake of brevity, terms such as “first” and “second” may not be used in the description to distinguish different elements. As long as it does not depart from the scope defined by the appended claims, the first element and/or the second element described in the appended claims can be interpreted as any element that meets the description in the specification.

In the present disclosure, the thickness, length, and width can be measured by using an optical microscope, and the thickness can be measured by the cross-sectional image in the electron microscope, but it is not limited thereto. In addition, a certain error may be present in a comparison with any two values or directions. If the first direction is perpendicular to the second direction, the angle between the first direction and the second direction may be between 80 degrees (≥80 degrees) and 100 degrees (≤100 degrees). If the first direction is parallel to the second direction, the angle between the first direction and the second direction may be between 0 degree (≥0 degree) and 10 degrees (≤10 degrees).

It should be noted that the technical solutions provided by different embodiments below may be interchangeable, combined or mixed to form another embodiment without departing from the spirit of the present disclosure.

Unless defined otherwise, all terms (including technical and scientific terms) used herein have the same meaning as commonly understood by one having ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined in the present disclosure.

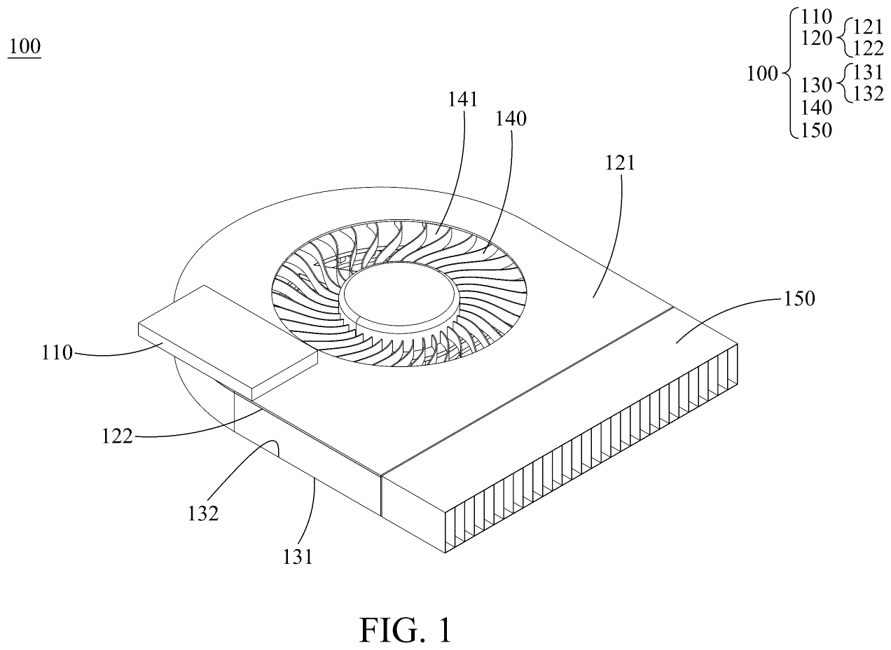

Please refer to FIG. 1, FIG. 1 is a schematic view of a heat dissipation assembly 100 according to some embodiments of the present disclosure.

As shown in FIG. 1, the heat dissipation assembly 100 may include a heat source 110, an upper cover 120, a lower cover 130, and a heat dissipation device 140.

The heat source 110 may generate thermal energy. According to some embodiments of the present disclosure, the heat source 110 may be a central processing unit (CPU) or a graphics processing unit (GPU).

According to some embodiments of the present disclosure, the upper cover 120 may be a thermoelectric generator chip (TEG chip). Furthermore, the upper cover 120 may include a first upper cover surface 121 and a second upper cover surface 122.

The first upper cover surface 121 and the second upper cover surface 122 may face opposite directions. Moreover, according to some embodiments of the present disclosure, the first upper cover surface 121 may “face outwardly”, and the second upper cover surface 122 may “face inwardly”.

The first upper cover surface 121 may be in contact with the heat source 110 to receive thermal energy from the heat source 110.

In the embodiment of FIG. 1, the first upper cover surface 121 may be in direct contact with the heat source 110. For example, the heat source 110 may directly abut the first upper cover surface 121.

It should be noted that even though the heat source 110 is disposed on one side of the air outlet 141 of the heat dissipation device 140 in FIG. 1; however, in fact, the heat source 110 may be disposed on multiple sides of the air outlet 141 of the heat dissipation device 140 or around the air outlet 141 of the heat dissipation device 140. According to some embodiments of the present disclosure, the heat source 110 may not block the air outlet 141 of the heat dissipation device 140.

Moreover, the dimensional relationship between the heat source 110 and the heat dissipation device 140 in FIG. 1 is only an example and is not intended to limit the embodiment of the present invention.

According to some other embodiments of the present disclosure, the first upper cover surface 121 may be in indirect contact with the heat source 110. For example, other media may be provided between the heat source 110 and the first upper cover surface 121.

The second upper cover surface 122 may face the heat dissipation device 140. Therefore, the heat dissipation device 140 may drive airflow to cool the second upper cover surface 122.

Since the first upper cover surface 121 receives thermal energy from the heat source 110 and the second upper cover surface 122 is cooled by the heat dissipation device 140, the temperature of the first upper cover surface 121 will be higher than the temperature of the second upper cover surface 122.

Since there is a temperature difference between the two sides of the upper cover 120, the upper cover 120 may generate electrical energy (e.g., voltage or current) and supply this electrical energy to other elements.

The lower cover 130 may be disposed opposite to the upper cover 120. The heat dissipation device 140 may be accommodated between the upper cover 120 and the lower cover 130.

The lower cover 130 may include a first lower cover surface 131 and a second lower cover surface 132. The first lower cover surface 131 and the second lower cover surface 132 may face opposite directions. Moreover, according to some embodiments of the present disclosure, the first lower cover surface 131 may “face outwardly”, and the second lower cover surface 132 may “face inwardly”.

The heat dissipation device 140 is located between the upper cover 120 and the lower cover 130, and the heat dissipation device 140 may be disposed adjacent to the second upper cover surface 122 and the second lower cover surface 132. Therefore, the heat dissipation device 140 may cool the second surface of the upper cover 122 and the second lower cover surface 132.

According to some embodiments of the present disclosure, the heat dissipation device 140 may have heat dissipation and cooling effects. For example, the heat dissipation device 140 may be a radiator, a fan, or a cooling source.

Please continue to refer to FIG. 1, the heat dissipation assembly 100 may further include a fin 150. The fin 150 may be disposed adjacent to the heat dissipation device 140 to promote heat dissipation efficiency of the heat dissipation assembly 100.

According to some embodiments of the present disclosure, the fin 150 may also directly contact the heat source 110. For example, the heat source 110 may also directly abut against the fin 150. Therefore, the heat source 110 may be in direct contact with the first upper cover surface 121 and the fin 150 at the same time, so as to promote heat dissipation of the heat source 110. In this embodiment, the heat source 110 may also be dissipated by another heat dissipation device.

According to some other embodiments of the present disclosure, the fin 150 may not be in direct contact with the heat source 110. Therefore, the heat source 110 may only be in direct contact with the first upper cover surface 121 to increase the temperature of the first upper cover surface 121, and to increase the temperature difference between the first upper cover surface 121 and the second upper cover surface 122, thereby increasing the electrical energy generated by the upper cover 120.

Even though the embodiment in FIG. 1 shows that the first upper cover surface 121 is in direct contact with the heat source 110, it is conceivable that in some other embodiments, the first lower cover surface 131 is in direct contact with the heat source 110 instead of the first upper cover surface 121 being in direct contact with heat source 110.

Even though there is no schematic view of the embodiment in which the first lower cover surface 131 is in direct contact with the heat source 110, it is still conceivable that the embodiment in which the first lower cover surface 131 is in direct contact with the heat source 110 is similar to the embodiment in which the first upper cover surface 121 is in direct contact with the heat source 110.

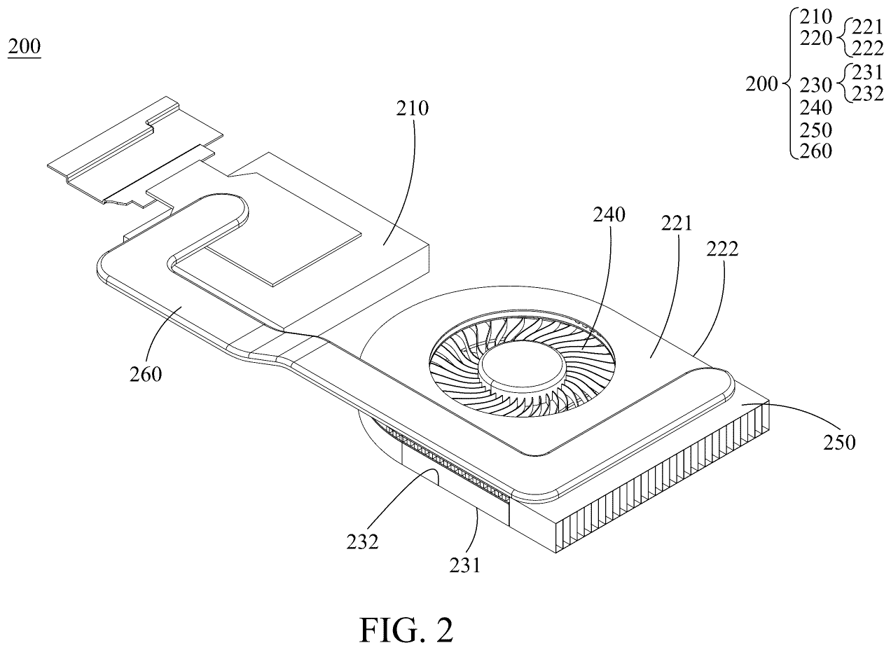

Please refer to FIG. 2, FIG. 2 is a schematic view of a heat dissipation assembly 200 according to some embodiments of the present disclosure.

As shown in FIG. 2, the heat dissipation assembly 200 may include a heat source 210, an upper cover 220, a lower cover 230, a heat dissipation device 240, a fin 250, and a heat pipe 260.

Most elements of the heat dissipation assembly 200 are similar to most elements of the heat dissipation assembly 100, and the similarities will not be described again.

In the embodiment of FIG. 2, the heat pipe 260 is in contact with heat source 210 to conduct thermal energy from heat source 210 away from heat source 210. The heat pipe 260 may extend from the heat source 210 to and be in contact with the first upper cover surface 221 of the upper cover 220, so that the first upper cover surface 221 of the upper cover 220 is in indirect contact with the heat source 210 via the heat pipe 260.

As shown in FIG. 2, the heat pipe 260 may also be in contact with the fin 250, so that the heat pipe 260 may conduct the thermal energy from the heat source 210 to the first upper cover surface 221 and the fin 250.

According to some other embodiments of the present disclosure, the heat pipe 260 may only be in contact with the heat source 210 and the first upper cover surface 221 without be in contact with the fin 250. In this way, the temperature of the first upper cover surface 221 may be increased, and the temperature difference between the first upper cover surface 221 and the second upper cover surface 222 may be increased, thereby increasing the electrical energy generated by the upper cover 220. In this embodiment, the heat source 210 may also be dissipated by another heat dissipation device.

According to some other embodiments of the present disclosure, the heat pipe 260 may be only in contact with the heat source 210 and the fin 250 without being in contact with the first surface 221 of the upper cover, and the heat pipe 260 may conduct thermal energy to the first upper cover surface 221 through the fin. For example, the heat source 210 may also directly abut against the fin 250.

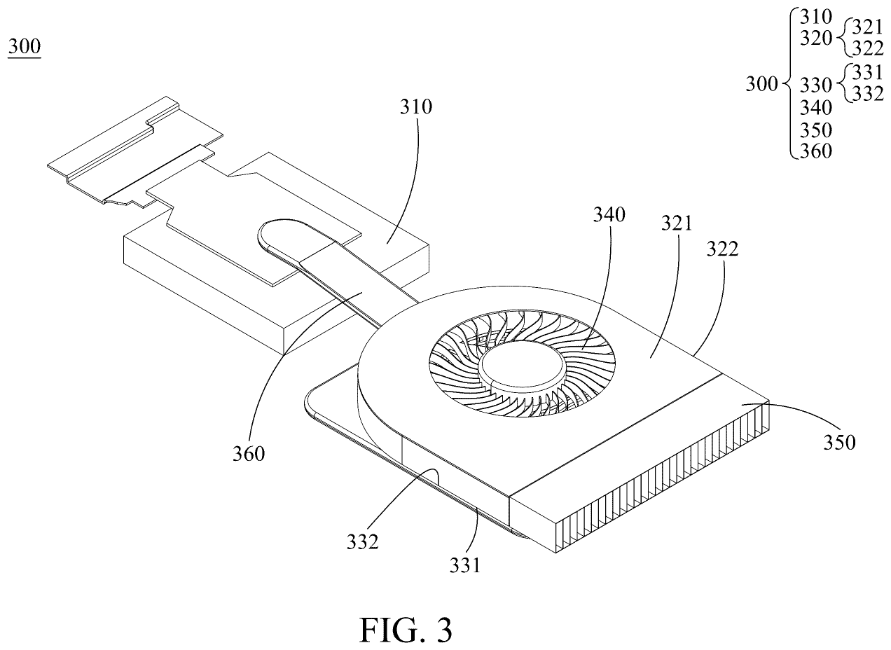

Please refer to FIG. 3, FIG. 3 is a schematic view of a heat dissipation assembly 300 according to some embodiments of the present disclosure.

As shown in FIG. 3, the heat dissipation assembly 300 may include a heat source 310, an upper cover 320, a lower cover 330, a heat dissipation device 340, a fin 350, and a heat pipe 360.

Most elements of the heat dissipation assembly 300 are similar to most elements of the heat dissipation assembly 100, and the similarities will not be described again.

The heat pipe 360 is in contact with the heat source 310 to conduct thermal energy from the heat source 310 away from the heat source 310. The heat pipe 360 may extend from the heat source 310 to and be in contact with the lower cover first surface 331 of the lower cover 330, so that the first lower cover surface 331 of the lower cover 330 is in indirect contact with the heat source 310 via the heat pipe 360.

In the embodiment of FIG. 3, the lower cover 330 may be a thermoelectric generator wafer (TEG wafer).

The second lower cover surface 332 may face the heat dissipation device 340, so the heat dissipation device 340 may drive airflow to cool the second surface 332 of the lower cover.

Since the first lower cover surface 331 receives thermal energy from the heat source 310 and the second lower cover surface 332 is cooled by the heat dissipation device 340, the temperature of the first lower cover surface 331 will be higher than the temperature of the second lower cover surface 332.

Since there is a temperature difference between the two sides of the lower cover 330, the lower cover 330 may generate electrical energy (e.g., voltage or current) and supply this electrical energy to other elements.

As shown in FIG. 3, the heat pipe 360 may also be in contact with the fin 350, so that the heat pipe 360 may conduct the thermal energy from the heat source 310 to the first lower cover surface 331 and the fin 350.

According to some other embodiments of the present disclosure, the heat pipe 360 may only be in contact with the heat source 310 and the first lower cover surface 331 without contacting the fin 350. In this way, the temperature of the first lower cover surface 331 may be increased, and the temperature difference between the first lower cover surface 331 and the second lower cover surface 332 may be increased, thereby increasing the electrical energy generated by the lower cover 330. In this embodiment, the heat source 310 may also be dissipated by another heat dissipation device.

According to some other embodiments of the present disclosure, the heat pipe 360 may only be in contact with the heat source 310 and the fin 350 without being in contact with the first lower cover surface 331, and the heat pipe 360 may conduct thermal energy to the first lower cover surface 331 through the fin. For example, the heat source 310 may also directly abut against the fin 350.

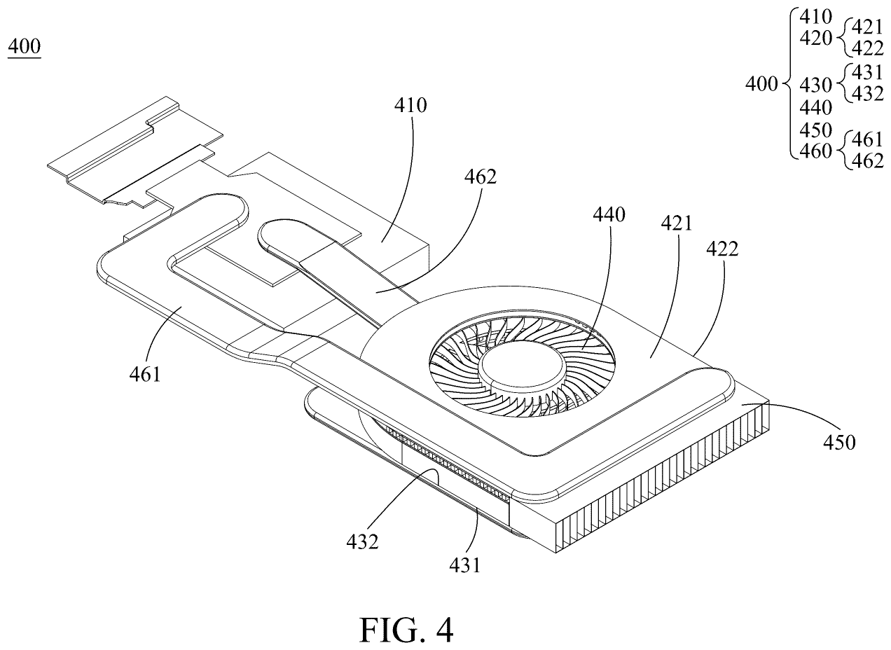

Please refer to FIG. 4, FIG. 4 is a schematic view of a heat dissipation assembly 400 according to some embodiments of the present disclosure.

As shown in FIG. 4, the heat dissipation assembly 400 may include a heat source 410, an upper cover 420, a lower cover 430, a heat dissipation device 440, a fin 450, and a heat pipe 460.

Most elements of the heat dissipation assembly 400 are similar to most elements of the heat dissipation assembly 100, and the similarities will not be described again.

Please continue to refer to FIG. 4, the heat pipe 460 may include an upper heat pipe 461 and a lower heat pipe 462.

In the embodiment of FIG. 4, the upper heat pipe 461 is in contact with the heat source 410 to conduct thermal energy from the heat source 410 away from the heat source 410. The upper heat pipe 461 may extend from the heat source 410 to and be in contact with the first upper cover surface 421 of the upper cover 420, so that the first upper cover surface 421 of the upper cover 420 is in indirect contact with the heat source 410 via the upper heat pipe 461.

In the embodiment of FIG. 4, both the upper cover 420 and the lower cover 430 may be thermoelectric generator chips (TEG chips).

The second upper cover surface 422 may face the heat dissipation device 440. Therefore, the heat dissipation device 440 may drive airflow to cool the second surface 422 of the upper cover.

Since the first upper cover surface 421 receives thermal energy from the heat source 410, and the second upper cover surface 422 is cooled by the heat dissipation device 440, the temperature of the first upper cover surface 421 will be higher than the temperature of the second upper cover surface 422.

Since there is a temperature difference between the two sides of the upper cover 420, the upper cover 420 may generate electrical energy (e.g., voltage or current) and supply this electrical energy to other elements.

As shown in FIG. 4, the upper heat pipe 461 may also be in contact with the fin 450, so that the upper heat pipe 461 may conduct the thermal energy from the heat source 410 to the first upper cover surface 421 and the fin 450.

According to some other embodiments of the present disclosure, the upper heat pipe 461 may only be in contact with the heat source 410 and the first upper cover surface 421 without being in contact with the fin 450. In this way, the temperature of the first upper cover surface 421 may be increased, and the temperature difference between the first upper cover surface 421 and the second upper cover surface 422 may be increased, thereby increasing the electrical energy generated by the upper cover 420. In this embodiment, the heat from the heat source 410 may also be dissipated by another heat dissipation device.

According to some other embodiments of the present disclosure, the upper heat pipe 461 may only be in contact with the heat source 410 and the fin 450 without being in contact with the first upper cover surface 421, and the upper heat pipe 461 may conduct thermal energy to the first upper cover surface 421 through the fin. For example, the heat source 410 may also directly abut against the fin 450.

Please continue to refer to FIG. 4. In the embodiment of FIG. 4, the lower heat pipe 462 is in contact with the heat source 410 to conduct thermal energy from the heat source 410 away from the heat source 410. The lower heat pipe 462 may extend from the heat source 410 to and be in contact with the first lower cover surface 431 of the lower cover 430 such that the first lower cover surface 431 of the lower cover 430 is in indirect contact with the heat source 410 via the heat pipe 460 (e.g., the lower heat pipe 462).

In the embodiment of FIG. 4, the lower cover 430 may be a thermoelectric generator wafer (TEG wafer).

The second lower cover surface 432 may face the heat dissipation device 440, so the heat dissipation device 440 may drive airflow to cool the second surface 432 of the lower cover.

Since the first lower cover surface 431 receives the thermal energy from the heat source 410, and the second lower cover surface 432 of the is cooled by the heat dissipation device 440, the temperature of the first lower cover surface 431 will be higher than the temperature of the second lower cover surface 432.

Since there is a temperature difference between the two sides of the lower cover 430, the lower cover 430 may generate electrical energy (e.g., voltage or current) and supply this electrical energy to other elements.

As shown in FIG. 4, the lower heat pipe 462 may also be in contact with the fin 450, so that the lower heat pipe 462 may conduct the thermal energy from the heat source 410 to the first lower cover surface 431 and the fin 450.

According to some other embodiments of the present disclosure, the lower heat pipe 462 may only be in contact with the heat source 410 and the first lower cover surface 431 without being in contact with the fin 450. In this way, the temperature of the first lower cover surface 431 may be increased, and the temperature difference between the first lower cover surface 431 and the second lower cover surface 432 may be increased, thereby increasing the electrical energy generated by the lower cover 430. In this embodiment, the heat from the heat source 410 may also be dissipated by another heat dissipation device.

According to some other embodiments of the present disclosure, the lower heat pipe 462 may only be in contact with the heat source 410 and the fin 450 without being in contact with the first lower cover surface 431, and the lower heat pipe 462 may conduct thermal energy to the first lower cover surface 431 through the fin. For example, the heat source 410 may also directly abut against the fin 450.

In the embodiment of FIG. 4, since both the upper cover 420 and the lower cover 430 of the heat dissipation assembly 400 may generate electrical energy, the electrical energy generated by the heat dissipation assembly 400 may be increased.

In general, the heat dissipation assembly of the embodiment of the present disclosure may convert the thermal energy generated by the heat source into electrical energy and may dissipate heat at the same time. Therefore, the heat dissipation assembly of the embodiment of the present disclosure may achieve a “heat recovery” effect.

In addition, the heat dissipation assembly of the embodiment of the present disclosure may have an effect of space-saving, so that the heat dissipation assembly of the embodiment of the present disclosure may be disposed in a device with space constraints. For example, the heat dissipation assembly of the embodiment of the present disclosure may be installed in a laptop computer, and may achieve heat recovery of the laptop computer without affecting the space configuration and heat dissipation efficiency of the laptop computer.

It should be noted that the heat dissipation assembly of the embodiment of the present disclosure may also be disposed in other devices with space constraints. For example, the heat dissipation assembly of the embodiment of the present disclosure may also be installed in mini computers, mobile phones and other equipment.

It should be further understood that even though the heat dissipation assembly of the embodiment of the present disclosure may have a space-saving effect, the heat dissipation assembly of the embodiment of the present disclosure is not limited to devices with space limitations. Therefore, it may be understood that the heat dissipation assembly of the embodiment of the present disclosure may also be disposed in a device with less space restrictions.

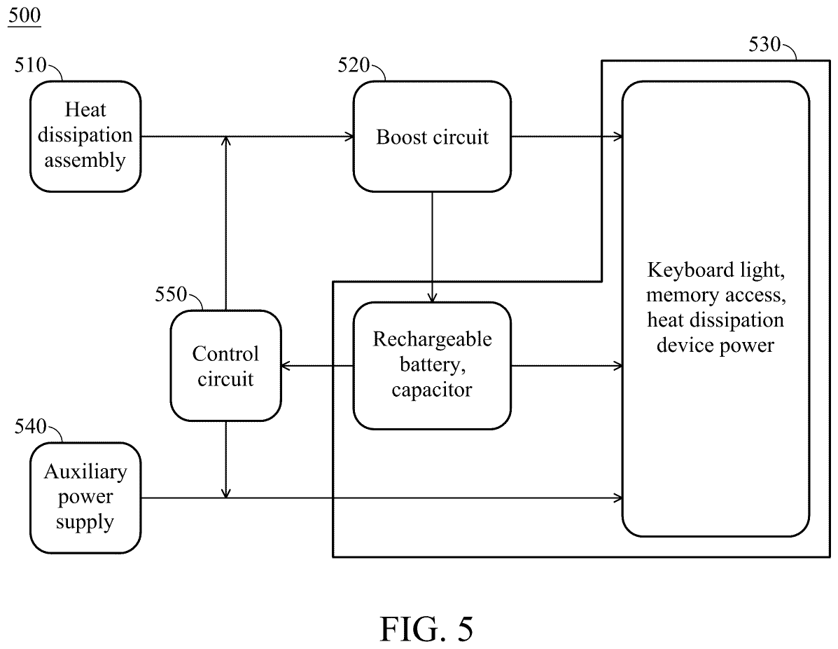

Please refer to FIG. 5, FIG. 5 is a schematic view of a circuit system 500 according to some embodiments of the present disclosure.

As shown in FIG. 5, the circuit system 500 may include a heat dissipation assembly 510, a boost circuit 520, an electronic element 530, an auxiliary power supply 540, and a control circuit 550.

The heat dissipation assembly 510 may be the heat dissipation assembly mentioned in this disclosure, such as the heat dissipation assembly 100, the heat dissipation assembly 200, the heat dissipation assembly 300, and the heat dissipation assembly 400.

The heat dissipation assembly 510 may generate a voltage 510a. The boost circuit 520 may receive the voltage 510a and adjust the voltage 510a to a voltage 520a that is suitable for the electronic element 530.

The electronic element 530 may receive the voltage 520a adjusted by the boost circuit 520 to drive the electronic element 530 for operating.

According to some embodiments of the present disclosure, the electronic element 530 may be one or more of a rechargeable battery, a capacitor, a keyboard light, a memory access, and a heat dissipation device power.

According to some embodiments of the present disclosure, one or more of the rechargeable battery and the capacitor may store electrical energy to supply one or more of the keyboard light, memory access, and heat dissipation device power.

The auxiliary power supply 540 may generate a second voltage 540a. The second voltage 540a may drive the electronic element 530 for operating.

The control circuit 550 may choose to provide the voltage 510a generated by the heat dissipation assembly 510 or the second voltage 540a generated by the auxiliary power supply 540 to the electronic element 530.

According to some embodiments of the present disclosure, when the voltage 510a generated by the heat dissipation assembly 510 is sufficient to drive the electronic element 530, the control circuit 550 may provide the voltage 510a generated by the heat dissipation assembly 510 to the electronic element 530.

According to some embodiments of the present disclosure, when the voltage 510a generated by the heat dissipation assembly 510 is insufficient to drive the electronic element 530, the control circuit 550 may provide the second voltage 540a generated by the auxiliary power supply 540 to the electronic element 530.

In this way, the voltage can be stably supplied to the electronic element 530, and when the electronic element 530 receives the voltage 510a generated by the heat dissipation assembly 510, the effect of energy saving can be achieved.

In general, the circuit system of the embodiment of the present disclosure may achieve the effect of energy saving by providing the electrical energy generated by the heat dissipation assembly (for example, the electrical energy generated by “heat recovery”) to the electronic elements.

In addition, the circuit system of the embodiment of the present disclosure may select the voltage to be provided to the electronic elements through the control circuit, so as to achieve the effect of energy saving and stable power supply.

Moreover, according to some embodiments of the present disclosure, the circuit system may be provided in a device with heat dissipation requirements. For example, the circuit system of the embodiment of the present disclosure may be installed in a laptop computer to provide electrical energy generated by “heat recovery” to the electronic elements of the laptop computer.

It should be noted that the circuit system of the embodiment of the present disclosure may also be installed in other devices with heat dissipation requirements to achieve the aforementioned effects.

Although the embodiments and the advantages of the present disclosure have been described above, it should be understood that those skilled in the art may make various changes, substitutions, and alterations to the present disclosure without departing from the spirit and scope of the present disclosure. It should be noted that different embodiments may be arbitrarily combined as other embodiments as long as the combination conforms to the spirit of the present disclosure. In addition, the scope of the present disclosure is not limited to the processes, machines, manufacture, composition, devices, methods and steps in the specific embodiments described in the specification. Those skilled in the art may understand existing or developing processes, machines, manufacture, compositions, devices, methods and steps from some embodiments of the present disclosure. Therefore, the scope of the present disclosure includes the aforementioned processes, machines, manufacture, composition, devices, methods, and steps. Furthermore, each of the appended claims constructs an individual embodiment, and the scope of the present disclosure also includes every combination of the appended claims and embodiments.

What is claimed is:

1. A heat dissipation assembly, comprising:
a heat source;
an upper cover, comprising:
a first upper cover surface, receiving the thermal energy from the heat source; and
a second upper cover surface; and
a heat dissipation device, located under the upper cover and adjacent to the second upper cover surface to cool the second upper cover surface,
wherein the upper cover is a thermoelectric generator chip.

2. The heat dissipation assembly as claimed in claim 1, wherein the heat source is in direct contact with the first upper cover surface.

3. The heat dissipation assembly as claimed in claim 1, wherein a temperature of the first upper cover surface is higher than a temperature of the second upper cover surface.

4. The heat dissipation assembly as claimed in claim 1, further comprising a lower cover located under the heat dissipation device, comprising:
a first lower cover surface, receiving the thermal energy from the heat source; and
a second lower cover surface, adjacent to the heat dissipation device,
wherein a temperature of the first lower cover surface is higher than a temperature of the second lower cover surface.

5. The heat dissipation assembly as claimed in claim 1, further comprising a heat pipe,
wherein the heat pipe is in contact with the heat source to conduct the thermal energy from the heat source away from the heat source.

6. The heat dissipation assembly as claimed in claim 5, wherein the heat pipe is in contact with the first upper cover surface to conduct the thermal energy from the heat source to the first upper cover surface.

7. The heat dissipation assembly as claimed in claim 5, further comprising a fin disposed adjacent to the upper cover,
wherein the heat pipe is in contact with the fin to conduct the thermal energy from the heat source to the fin.

8. The heat dissipation assembly as claimed in claim 7, wherein the heat pipe is in contact with the first upper cover surface and the fin, so as to conduct the thermal energy from the heat source to the first upper cover surface and the fin.

9. A heat dissipation assembly, comprising:
a heat source;
a lower cover, comprising:
a first lower cover surface, receiving the thermal energy from the heat source; and
a second lower cover surface; and
a heat dissipation device, located above the lower cover and adjacent to the second lower cover surface to cool the second lower cover surface,
wherein the lower cover is a thermoelectric generator chip.

10. The heat dissipation assembly as claimed in claim 9, wherein the heat source is in direct contact with the first lower cover surface.

11. The heat dissipation assembly as claimed in claim 9, wherein a temperature of the first lower cover surface is higher than a temperature of the second lower cover surface.

12. The heat dissipation assembly as claimed in claim 9, further comprising an upper cover located above the heat dissipation device, comprising:
a first upper cover surface, receiving the thermal energy from the heat source; and
a second upper cover surface, adjacent to the heat dissipation device,
wherein a temperature of the first upper cover surface is higher than a temperature of the second upper cover surface.

13. The heat dissipation assembly as claimed in claim 9, further comprising a heat pipe,
wherein the heat pipe is in contact with the heat source to conduct the thermal energy from the heat source away from the heat source.

14. The heat dissipation assembly as claimed in claim 13, wherein the heat pipe is in contact with the first lower cover surface to conduct the thermal energy from the heat source to the first lower cover surface.

15. The heat dissipation assembly as claimed in claim 13, further comprising a fin disposed adjacent to the lower cover,
wherein the heat pipe is in contact with the fin to conduct the thermal energy from the heat source to the fin.

16. The heat dissipation assembly as claimed in claim 15, wherein the heat pipe is in contact with the first lower cover surface and the fin, so as to conduct the thermal energy from the heat source to the first lower cover surface and the fin.

17. A circuit system, comprising:
the heat dissipation assembly as claimed in any one of claim 1, generating a voltage;
a boost circuit, adjusting the voltage from the heat dissipation assembly; and
an electronic element, receiving the voltage adjusted by the boost circuit.

18. The circuit system as claimed in claim 17, wherein the electronic element is one or more of a rechargeable battery, a capacitor, a keyboard light, a memory access, and a heat dissipation device power.

19. The circuit system as claimed in claim 17, further comprising:
an auxiliary power supply, generating a second voltage; and
a control circuit,
wherein when the voltage generated by the heat dissipation assembly is insufficient to drive the electronic element, the control circuit provides the second voltage generated by the auxiliary power supply to the electronic element.

20. The circuit system as claimed in claim 19, wherein when the voltage generated by the heat dissipation assembly is sufficient to drive the electronic element, the control circuit provides the voltage generated by the heat dissipation assembly to the electronic element.
